(19) United States
(12) Patent Application Publication
(10) Pub. No.: US 2007/0111403 A1
(43) Pub. Date: May 17, 2007

(54) Polycide fuse with reduced programming time

(76) Inventors: Chun Jiang, San Jose, CA (US); Sunil Mehta, San Jose, CA (US); Stewart Logie, Campbell, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/274,037

(22) Filed: Nov. 15, 2005

(51) Int. Cl. H01L 21/82; H01L 27/10; H01L 21/8242

(52) U.S. Cl. 438/132; 438/253; 257/209

(57) ABSTRACT

In one embodiment, a polycide fuse is provided that includes: a polysilicon layer; a silicide layer formed on the polysilicon layer; and a silicon nitride layer formed on the silicide layer by RTCVD, the silicon nitride layer having a relatively low hydrogen concentration and relatively low mechanical stress.

### TECHNICAL FIELD

The present invention relates generally to semiconductor devices and, more particularly, to an electrically programmable polycide fuse having improved reliability and programming speed.

### BACKGROUND

Data storage devices and memories may be classified into two types: volatile and non-volatile. Whereas power must be provided to a volatile memory to maintain its stored information, a non-volatile memory may be powered down yet still retain the stored information. Examples of non-volatile memory include Electrically Erasable Programmable Read Only Memory (EEPROM) and flash. Although these non-volatile memories have proven to be very popular because they retain data without requiring power, they are generally incompatible with conventional Complementary Metal Oxide Semiconductor (CMOS) processing techniques.

This incompatibility introduces a problem in that CMOS is a dominant technology used in the manufacture of a vast number of integrated circuits. Should an integrated circuit require non-volatile storage, additional process steps besides the CMOS process steps already implemented to manufacture the remaining components will be necessary. Such additional process steps introduce substantial cost. To avoid this cost, polycide fuses compatible with CMOS technology have been developed to implement a non-volatile memory. In contrast to EEPROM and flash, a polycide fuse memory is a one time programmable (OTP) memory in that once a fuse is programmed, it cannot be re-programmed. Each polycide fuse is manufactured in a non-programmed state. To program a polycide fuse, current is passed through the fuse until at least the silicide layer in the polycide fuse becomes open circuited (producing a “blown” fuse). To read a polycide fuse memory, the resistance of each fuse is compared to a threshold resistance. If the fuse has a resistance above the threshold resistance (which may have a value of, for example, 10K Ω), the fuse is judged to be programmed. On the other hand, if the fuse has a resistance below the threshold resistance, the fuse is judged to be not programmed.

As circuit dimensions continue to shrink for CMOS technology, the available power supply voltage levels also decrease to avoid damaging circuit components. For example, it is conventional to have CMOS circuitry that cannot tolerate voltages greater than 3.3 V. Indeed, CMOS circuitry has been developed that cannot tolerate voltages greater than 2.5 V. Such relatively-low voltage levels in turn reduce the available current than can be forced through a polycide fuse so that it can be programmed. It is thus conventional to require as much as 200 μs to program a polycide fuse, thereby leading to undesirable delays in programming substantial numbers of such fuses.

Another problem with conventional polycide fuses is reliability. A polycide fuse needs to be reliable in both the programmed and non-programmed states. To be reliable in the non-programmed state, a polycide fuse should consistently have a resistance below the threshold resistance. Conversely, a reliable programmed fuse should consistently have a resistance above the threshold resistance. However, the shrinking dimensions of modern CMOS processes have affected polycide fuse reliability in both the non-programmed and programmed states. In particular, it has been found that commonly-used deposition techniques for making polycide fuses produce a silicon nitride layer having a relatively high hydrogen concentration. It is known that hydrogen contained within deposited silicon nitride may diffuse into adjacent structures and compromise device reliability. For example, plasma-enhanced-chemical-vapor-deposition (PECVD) is widely known to produce silicon nitride having such relatively high hydrogen concentrations. Although increasing PECVD deposition temperature reduces the hydrogen concentration, operation of PECVD above 480° C. is problematic. Another commonly-performed silicon nitride deposition technique, low-pressure-chemical-vapor-deposition (LPCVD), can be performed at much higher temperatures such as 800° C., thereby largely removing free hydrogen from the deposited silicon nitride. However, the use of LPCVD places relatively large stresses on the deposited silicon nitride and underlying structures in the polycide fuse. As a result, it is conventional to produce polycide fuses with silicon nitride layers having relatively high concentrations of hydrogen.

Accordingly, there is need in the art for a polycide fuse having improved reliability and reduced programming time.

### SUMMARY

In accordance with an embodiment of the invention, a polycide fuse includes: a polysilicon layer; a silicide layer formed on the polysilicon layer; and a silicon nitride layer formed on the silicide layer, the silicon nitride layer having a relatively low hydrogen concentration and a relatively low mechanical stress.

In accordance with another embodiment of the invention, a method of manufacturing a polycide fuse includes the acts of: forming a polysilicon layer; forming a silicide layer on the polysilicon layer; and forming a silicon nitride layer on the silicide layer using RTCVD.

In accordance with another embodiment of the invention, a polycide fuse includes: a polysilicon layer; a silicide layer formed on the polysilicon layer; and a silicon nitride layer formed on the silicide layer by RTCVD, the silicon nitride layer thereby having a relatively low hydrogen concentration and a relatively low mechanical stress, wherein the polycide fuse includes a cathode, an anode, and a fuse neck joining the cathode and the anode, the fuse neck having a length of at least one micron.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 is a plan view of a polycide fuse in accordance with an embodiment of the invention.

FIG. 2. is cross-sectional view of the polycide fuse of FIG. 1 taken along line A:A.

FIG. 3 illustrates the transient programming currents for a variety of polycide fuses in accordance with embodiments of the invention.

FIG. 4 illustrates the programmed resistance as a function of the power supply voltage for a polycide fuse in accordance with an embodiment of the invention.

FIG. 5 is a block diagram of a programmable logic device having an OTP memory formed using an array of polycide fuses in accordance with an embodiment of the invention.

Embodiments of the present invention and their advantages are best understood by referring to the detailed description that follows. It should be appreciated that like reference numerals are used to identify like elements illustrated in one or more of the figures.

### DETAILED DESCRIPTION

Reference will now be made in detail to one or more embodiments of the invention. While the invention will be described with respect to these embodiments, it should be understood that the invention is not limited to any particular embodiment. On the contrary, the invention includes alternatives, modifications, and equivalents as may come within the spirit and scope of the appended claims. Furthermore, in the following description, numerous specific details are set forth to provide a thorough understanding of the invention. The invention may be practiced without some or all of these specific details. In other instances, well-known structures and principles of operation have not been described in detail to avoid obscuring the invention.

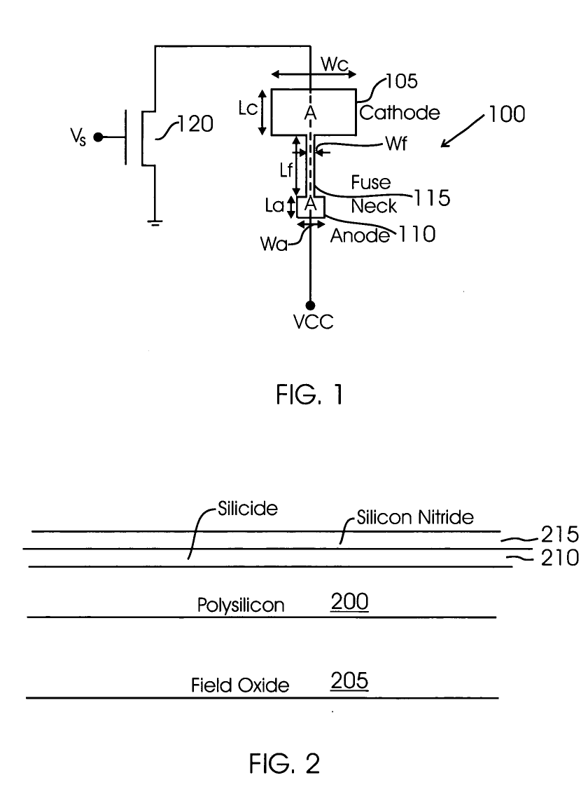

Turning now to the drawings, FIG. 1 shows a top view of an exemplary polycide fuse 100 having improved reliability and programming characteristics. Polycide fuse 100 includes a cathode 105 and an anode 110 that are joined by a fuse neck 115. Fuse neck 115 in the non-programmed state is conductive such that fuse 100 has a relatively low resistance such as 100 Ω or less. To program polycide fuse 100, a switch such as NMOS transistor 120 is turned on by bringing a gate voltage Vg high so that cathode 105 is connected to a local ground terminal. Because anode 110 is connected to a power supply voltage terminal VCC, a current of electrons will flow from the local ground terminal through fuse 100 into the power supply voltage terminal if NMOS transistor 120 is conducting.

A cross-sectional view of polycide fuse 100 is illustrated in FIG. 2. An undoped polysilicon layer 200 is formed on an insulating layer such as a field oxide layer 205. As known in the art, polysilicon layer 200 may be deposited onto field oxide layer 205 using a variety of chemical vapor deposition (CVD) or other techniques. Polysilicon layer 200 is then silicided with a suitable metal such as, e.g., nickel, platinum, cobalt, or titanium to form silicide layer 210. A silicon nitride cap layer 215 deposited onto silicide layer 210 insulates silicide layer 210. In addition, silicon nitride layer 215 may also function as an etch stop and a diffusion barrier. The thicknesses of each layer will depend upon the particular semiconductor process being used to form polycide fuse 100. In one embodiment, field oxide layer 205 may be approximately 280 nm in thickness, polysilicon layer 200 may be approximately 70 nm in thickness, silicide layer 210 may comprise a layer of cobalt silicide of approximately 40 nm in thickness, and silicon nitride layer 215 may be approximately 80 nm in thickness.

Referring back to FIG. 1, fuse 100 may be dimensioned to promote rapid programming. In one embodiment, the length (Lc) of cathode 105 is one μm and width (Wc) of cathode 105 is also one μm; the width of fuse neck 115 (Wf) is 0.06 μm and its length (Lf) is 1.2 μm; and the length (La) for anode 110 is 0.8 μm and its width (Wa) is 0.5 μm. It will be appreciated, however, that the dimensions for the cathode, fuse neck, and anode may be varied to suit individual design needs.

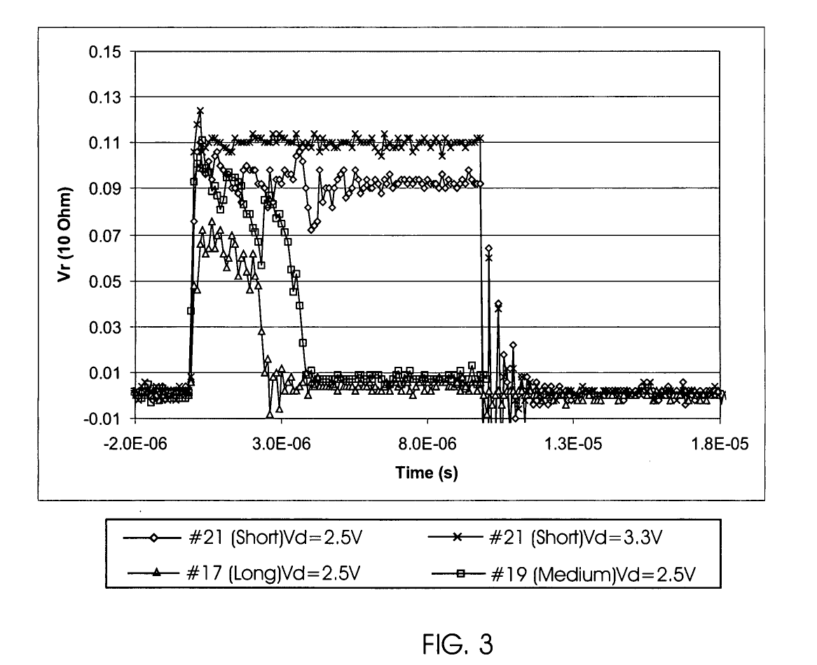

The programming process may be better understood with reference to FIG. 3, which illustrates the voltage Vr across a 10 Ω resistor (not illustrated) in series with the source of NMOS transistor 120 of FIG. 1 for three different embodiments of polycide fuse 100. To induce a programming current, the gate voltage Vg on NMOS transistor 120 was raised to the power supply voltage for 10 μs. By Ohm's law, the voltage Vr will be proportional to the transient programming current flowing through polycide fuse 100. The three embodiments differed only by their fuse neck length Lf. The remaining dimensions were as described above. In a first embodiment denoted as #17 (long), the fuse neck length was 1.2 μm. In a second embodiment denoted as # 19 (medium), the fuse neck length was 1.0 μm. In a third embodiment denoted as #21 (short), the fuse neck length was 0.8 μm. For the medium and long fuses (tested with a power supply voltage VCC of 2.5V), the programming transient current may be seen to include an initial conducting state followed by a constant conduction state whereas the short fuse (tested with VCC equaling 2.5V and also 3.3V) had only the constant conduction state. The initial conduction state corresponds to a transient programming current of approximately ten to six mA. The constant conduction state corresponds to a polycide fuse resistance of approximately three to four KΩ. It is believed that the end of the initial conducting state corresponds to a total depletion of the silicide layer by electromigration. It is further believed that the second conduction state is induced by intrinsic carriers excited by thermal runaway at the order of 850° C. after polycide depletion. The long fuse (#17) has a higher initial resistance (approximately 190 Ω), which induces a higher heating and temperature gradient that expedites the electromigration process in the initial conducting state. This temperature gradient is further increased if the cathode is larger than the anode as seen in FIG. 1. In addition, it may be observed that programming speeds at power supply voltage levels of 3.3 V or less are enhanced if fuse neck 115 has a length of at least one μm and a width of less than 0.1 μm.

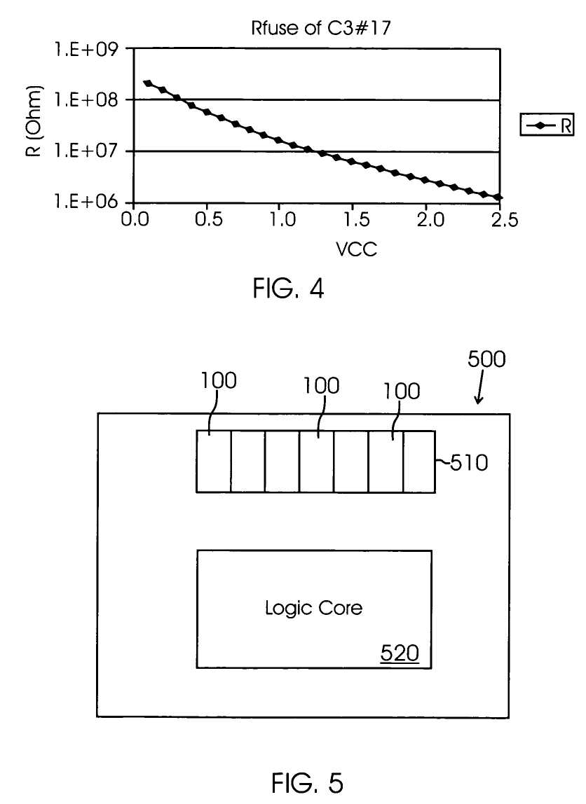

Turning now to FIG. 4, the programmed fuse resistance for the long fuse (#17) is illustrated as a function of the power supply voltage VCC. Although the programmed resistance decreases as VCC increases, the ratio of the programmed resistance to the initial resistance of 190 Ω is always greater than 10,000 such that the judging of whether such a polycide fuse has been programmed may be performed accurately. It may be seen that the accuracy of such judgment may be increased if the resistance of a programmed fuse is determined by using a lower sensing voltage than the available power supply voltage. However, programming speed is increased if the fuse is blown using the highest available power supply voltage. For example, fuse # 17 may be programmed in as little as 0.15 μs at a power supply voltage of 3.3V.

Programming speed may be significantly increased (and programming time thus reduced) by adapting polycide fuse 100 such that the transient programming current is largely confined to silicide layer 210 (FIG. 2). In general, if polysilicon layer 200 is doped, its resistance will be lower as compared to an undoped polysilicon layer. Referring back to FIG. 2, it may be seen that by forming polysilicon layer 200 as an undoped layer, more of the transient programming current will be carried by silicide layer 210. In this fashion, the programming speed and efficiency is increased.

It will be appreciated that the manufacture of polycide fuse 100 is entirely compatible with conventional CMOS processing techniques such as the CS100 A process such that no additional processing steps are necessary besides those already being performed to manufacture the remaining components. However, as discussed above, conventional silicon nitride deposition techniques produce silicon nitride layers having relatively high concentrations of hydrogen that adversely affect polycide fuse reliability. In embodiments of the present invention, silicon nitride layer 215 (FIG. 2) is deposited using a rapid-thermal-chemical-vapor-deposition (RTCVD) process such that silicon nitride layer 215 has a relatively low concentration of hydrogen.

In one embodiment, the RTCVD process deposits silicon nitride layer 215 at a temperature of about 500° C. to about 650° C. Those skilled in the art will appreciate that the deposition of silicon nitride in an RTCVD system can be carried out in a single-wafer deposition process in a relatively short period of time. Since the RTCVD process is carried out on a single wafer, the temperature to which the substrate is subjected can be controlled to minimize hydrogen incorporation into the silicon nitride material. Further, the precise temperature control also permits silicon nitride layer 215 to be deposited with a relatively low film stress. The relatively low deposition temperature avoids undesirable diffusion of impurities previously introduced into the underlying layers within polycide fuse 100. Further, previously formed alloys, such as silicide layer 210 are not degraded during the RTCVD process. Additional details of suitable RTCVD processes are disclosed in U.S. patent application Ser. No. 11/013,240, filed Dec. 14, 2004, the contents of which are incorporated by reference in their entirety.

Advantageously, embodiments of polycide fuse 100 may be incorporated into other devices such as, for example, programmable logic devices to form OTP memories. Turning now to FIG. 5, a programmable logic device 500 includes an OTP memory 510 formed from an array of polycide fuses 100. OTP memory 510 may be used for any application compatible with OTP programming restraints. For example, OTP memory 510 may be programmed with security keys. During operation of programmable logic device 500, a logic core 520 may read the contents of OTP memory 510 and function accordingly.

Embodiments described above illustrate but do not limit the invention. For example, although various features have been described with reference to particular materials and doping, it will be appreciated that other implementations are also contemplated by the present disclosure. It should also be understood that numerous modifications and variations are possible in accordance with the principles of the present invention. Moreover, no limitations from the specification are intended to be read into any claims unless those limitations are expressly included in the claims. Accordingly, the scope of the invention is defined by the following claims.

We claim:

1. A polycide fuse, comprising:
a polysilicon layer;
a silicide layer formed on the polysilicon layer; and
a silicon nitride layer formed on the silicide layer by RTCVD, the silicon nitride layer having a relatively low hydrogen concentration and a relatively low mechanical stress.

2. The polycide fuse of claim 1, wherein the polycide fuse includes a cathode, an anode, and a fuse neck joining the cathode and the anode.

3. The polycide fuse of claim 2, wherein the cathode is larger than the anode.

4. The polycide fuse of claim 2, wherein the fuse neck has a length of at least one micron.

5. The polycide fuse of claim 2, wherein the fuse neck has a width of less than 0.1 micron.

6. The polycide fuse of claim 1, wherein the polysilicon layer is undoped.

7. The polycide fuse of claim 2, wherein the anode is connected to a power supply terminal and the cathode couples to a ground terminal through a programming transistor.

8. The polycide fuse of claim 7, wherein the programming transistor is an NMOS transistor.

9. A method of manufacturing a polycide fuse, comprising:
forming a polysilicon layer;
forming a silicide layer on the polysilicon layer; and
forming a silicon nitride layer on the silicide layer using RTCVD.

10. The method of claim 9, wherein forming the polysilicon layer comprises forming an undoped polysilicon layer.

11. The method of claim 9, wherein forming the silicon nitride layer comprises using RTCVD at a temperature of about 500° C. to 650° C.

12. The method of claim 9, wherein forming the silicon nitride layer comprises forming an etch stop layer.

13. The method of claim 9, wherein forming the silicon nitride layer comprises forming a diffusion barrier layer.

14. A polycide fuse, comprising:
a polysilicon layer;
a silicide layer formed on the polysilicon layer; and
a silicon nitride layer formed on the silicide layer by RTCVD, the silicon nitride layer thereby having a relatively low hydrogen concentration and a relatively low mechanical stress, wherein the polycide fuse includes a cathode, an anode, and a fuse neck joining the cathode and the anode, the fuse neck having a length of at least one micron.

15. The polycide fuse of claim 14, wherein the silicide layer is a cobalt silicide layer.

16. The polycide fuse of claim 14, wherein the polysilicon layer is undoped.

17. The polycide fuse of claim 14, wherein the polycide fuse is integrated into a programmable logic device.

18. The polycide fuse of claim 14, wherein the cathode is larger than the anode.

19. The polycide fuse of claim 14, wherein the fuse neck has a width of less than 0.1 micron.

20. The polycide fuse of claim 14, wherein the polysilicon layer is formed on a field oxide layer.
